(19) United States
(12) Patent Application Publication
(10) Pub. No.: US 2016/0013304 A1
(43) Pub. Date: Jan. 14, 2016

(54) A RADIO FREQUENCY POWER DEVICE FOR IMPLEMENTING ASYMMETRIC SELF-ALIGNMENT OF THE SOURCE, DRAIN AND GATE AND THE PRODUCTION METHOD THEREOF

(71) Applicant: FUDAN UNIVERSITY, Shanghai (CN)

(72) Inventors: Pengfei Wang, Shanghai (CN); Xiaoyong Liu, Shanghai (CN); Wei Zhang, Shanghai (CN); Qingqing Sun, Shanghai (CN); Peng Zhou, Shanghai (CN)

(21) Appl. No.: 14/651,992

(22) PCT Filed: Mar. 25, 2014
(86) PCT No.: PCT/CN2014/074011

§ 371 Date: Jun. 12, 2015

(30) Foreign Application Priority Data
Mar. 25, 2013 (CN) 201310098145.5
Mar. 25, 2013 (CN) 201310098164.8
Mar. 25, 2013 (CN) 201310098173.7

(51) Int. Cl. H01L 29/778; H01L 29/205; H01L 29/40; H01L 21/02; H01L 29/66; H01L 21/308; H01L 21/285; H01L 21/3213; H01L 29/207; H01L 29/45; H01L 29/20; H01L 21/306

(52) U.S. Cl. CPC H01L 29/7787; H01L 29/2003; H01L 29/205; H01L 29/402; H01L 21/0254; H01L 21/30612; H01L 21/3081; H01L 21/28575; H01L 21/32133; H01L 29/207; H01L 21/02164; H01L 21/0217; H01L 29/452; H01L 29/66522; H01L 29/66462

(57) ABSTRACT

The present disclosure relates to the technical field of radio frequency power devices, and more specifically, to a radio frequency power device for implementing the self-position alignment of asymmetric source, drain and gate and the production method thereof. In the radio frequency power device for implementing asymmetric self-alignment of the source, drain and gate according to the present disclosure, gate sidewalls are utilized to implement the self-position alignment of the source, drain and gate, thereby reducing parameter drift of products; besides, the source and drain of the device can be formed by the alloying process, the iron implanting process or epitaxy process after formation of the gate since the gate is protected by the passivating layer, featuring a simple technological process while reducing the parasitic source-drain resistances and enhancing the electrical properties of the radio is frequency power device.

### BACKGROUND OF THE DISCLOSURE

1. Technical Field

The present disclosure relates to the field of radio frequency power devices, and more specifically, to a radio frequency power device for implementing asymmetric self-alignment of the source, drain and gate and the production method thereof.

2. Description of Related Art

The high electron mobility transistor (HEMT) is widely regarded as one of the most promising high-speed electronic devices. With advantageous features, such as ultra high speed, low power consumption and low noise level (especially at low temperature), the HEMT device is capable of satisfying the special needs of ultra high-speed computers, signal processing, satellite communications, etc., in purpose and hence receives much attention. As a new generation of microwave and millimeter-wave devices, the HEMT has unraveled advantages in frequency, gain and efficiency. After more than a decade of development, the HEMT device possesses the properties of excellent microwave and millimeter wave and becomes a main device for low-noise microwave and millimeter-wave amplifiers in fields like 2˜100 GHz satellite communications and radio astronomy. Moreover, the HEMT device is also used for making the core parts of microwave mixers, oscillators and broadband traveling-wave amplifiers.

GaN-based HEMT radio frequency power devices in the prior art are mostly produced by using the gate-last process. The process flow of the production mainly includes: first, make a source and a drain; photo-etch ohmic contact holes, form a multi-layer electrode structure by electron-beam evaporation, form source-drain contact by use of the lift-off process, and form good source-drain ohmic contact at 900° C. in 30 seq thermal annealing (RTA) equipment under the protection of argon gas; next, photo-etch the regions that need to be etched away, and etch steps by using a piece of reactive ion beam etching (RIE) equipment while introducing boron chloride; finally, form Schottky barrier gate metal by using photo-etching, electro-beam evaporation and lift-off processes again. However, as the device becomes smaller and smaller, it is difficult to implement accurate position alignment between the gate and the source, drain of the HEMT device by means of the gate-last process, resulting in parameter drift of products.

### SUMMARY OF THE DISCLOSURE

The object of the present disclosure is to provide a radio frequency power device for implementing asymmetric self-alignment of the source, drain and gate and the production method thereof so as to implement the self-position alignment between the gate and the source, drain of radio frequency power devices, reduce parameter drift of products and enhance the electrical properties of radio frequency power devices.

The present disclosure provides a radio frequency power device for implementing asymmetric self-alignment of the source, drain and gate, comprising:

an AlGaN buffer layer, a GaN channel layer and an AlGaN isolating layer formed in turn on the substrate;

and a gate dielectric layer formed on the AlGaN isolating layer;

a gate stack region formed on the gate dielectric layer, including a gate and a passivating layer on the gate;

a first gate sidewall formed on either side of the gate stack region;

a drain and a source formed respectively on the outer side of the first gate sidewalls on both sides of the gate stack region;

a second gate sidewall formed between the first gate sidewall close to one side of the drain and the drain.

Furthermore, a field plate is formed on the first gate sidewall close to the drain, wherein the field plate is connected with the source and extends over the second gate sidewall and the passivating layer on the gate along the length of the current channel of the device.

Furthermore, the source and the drain are located on the AlGaN isolating layer and formed by alloy materials.

Furthermore, the source and the drain are located in the AlGaN isolating layer and formed by the silicon iron doped region in the AlGaN isolating layer.

Furthermore, the source and the drain are located on the GaN channel layer and formed by silicon doped GaN or AlGaN materials.

The present disclosure also provides a method for producing the radio frequency power device for implementing asymmetric self-alignment of the source, drain and gate as described above, and the specific steps are as follows:

deposit an AlGaN buffer layer, a GaN channel layer and an AlGaN isolating layer in turn on the substrate; etch the AlGaN isolating layer, the GaN channel layer and the AlGaN buffer layer in turn with a photo-resist as the etching stop layer to form an active region, followed by removal of the resist;

deposit the first layer of insulating film, the first layer of conductive film and the second layer of insulating film in turn on the exposed surface of the structure formed;

define the location of the gate stack region of the device by photo-etching and development;

etch away the second layer of insulating film and the first layer of conductive film exposed in turn with a photo-resist as the etching stop layer, followed by removal of the resist, in this way the remaining first layer of conductive film and second layer of insulating film form the gate stack region which comprises the gate of the device and the passivating layer on the gate;

deposit the third layer of insulating film on the exposed surface of the structure formed, and etch the third layer of insulating film to form a first gate sidewall on either side of the gate stack region;

deposit a layer of polysilicon on the exposed surface of the structure formed, etch back the polysilicon formed, but the polysilicon at the source is not etched away;

deposit the fourth layer of insulating film on the exposed surface of the structure formed, and etch the fourth layer of insulating film to form the second gate sidewall on the side of the gate stack region close to the drain;

etch away the remaining polysilicon, and continue to etch away the first layer of insulating film exposed.

The production method of a radio frequency power device for implementing asymmetric self-alignment of the source, drain and gate also comprises:

form a pattern by the photo-etching process to define the locations of the source and the drain respectively;

form the source and drain of the device by the lift-off process and the alloying process;

form a field plate on the first gate sidewall close to the drain, wherein the field plate is connected with the source and extends over the second gate sidewall and the passivating layer on the gate along the length of the current channel of the device.

The production method of a radio frequency power device for implementing asymmetric self-alignment of the source, drain and gate also comprises:

form a pattern by the photo-etching process and expose the locations of the source and the drain by means of a pattern;

implant silicon irons into the AlGaN isolating layer by the iron implanting process to form the source and drain of the device;

form a field plate on the first gate sidewall close to the drain, wherein the field plate is connected with the source and extends over the second gate sidewall and the passivating layer on the gate along the length of the current channel of the device.

The production method of a radio frequency power device for implementing asymmetric self-alignment of the source, drain and gate also comprises:

continue to etch away the exposed AlGaN isolating layer to expose the GaN channel layer formed;

form a pattern by the photo-etching process and expose the locations of the source and the drain by means of a pattern;

grow silicon doped GaN or AlGaN by the epitaxy process to form the source and drain of the device on the exposed GaN channel layer;

form a field plate on the first gate sidewall close to the drain, wherein the field plate is connected with the source and extends over the second gate sidewall and the passivating layer on the gate along the length of the current channel of the device.

The production method of a radio frequency power device for implementing asymmetric self-alignment of the source, drain and gate, wherein the first layer of insulating film is any one of silicon oxide, silicon nitride, hafnium oxide or Al₂O₃, while the second layer of insulating film, the third layer of insulating film and the fourth layer of insulating film are any one of silicon oxide or silicon nitride.

The production method of a radio frequency power device for implementing asymmetric self-alignment of the source, drain and gate, wherein the first layer of conductive film is chromium, nickel or tungsten-containing alloy.

In the radio frequency power device for implementing asymmetric self-alignment of the source, drain and gate according to the present disclosure, gate sidewalls are utilized to implement the self-position alignment of the source, drain and gate, thereby reducing parameter drift of products; besides, the source and drain of the device can be formed directly by the alloying process, the iron implanting process or epitaxy process after formation of the gate since the gate is protected by the passivating layer, thereby reducing the parasitic source-drain resistances and enhancing the electrical properties of the radio frequency power device.

### BRIEF DESCRIPTION OF THE SEVERAL VIEWS OF THE DRAWINGS

FIG. 1 illustrates a cross section of the first embodiment of the radio frequency power device for implementing asymmetric self-alignment of the source, drain and gate disclosed by the present disclosure.

FIG. 2 illustrates a cross section of the second embodiment of the radio frequency power device for implementing asymmetric self-alignment of the source, drain and gate disclosed by the present disclosure.

FIG. 3 illustrates a cross section of the third embodiment of the radio frequency power device for implementing asymmetric self-alignment of the source, drain and gate disclosed by the present disclosure.

FIG. 4 illustrates one embodiment of the radio frequency power device array consisting of the radio frequency power device for implementing asymmetric self-alignment of the source, drain and gate disclosed by the present disclosure, wherein FIG. 4b is the vertical view of the radio frequency power device array and FIG. 4a is the cross-sectional view of the structure shown in FIG. 4b along Line A-A.

FIG. 5 to FIG. 21 is the process flow diagram of the production method of the radio frequency power device for implementing asymmetric self-alignment of the source, drain and gate according to the present disclosure.

### DETAILED DESCRIPTION OF THE DISCLOSURE

The present disclosure is further detailed by the embodiments in combination with the drawings. For the convenience of description, the thickness of the layers and regions is increased or reduced in the figures, so those indicated are not the actual sizes. Despite the fact that these figures do not reflect the actual size of the device exactly, they completely reflect the mutual relationship in position among regions and constituent structures, especially the upper and lower as well as adjacent relationships among the constituent structures.

FIG. 1 to FIG. 3 are three embodiments of the radio frequency power device for implementing asymmetric self-alignment of the source, drain and gate provided by the present disclosure, and the figures are the cross-sectional views along the length of the current channel of the device. As shown in FIG. 1 to FIG. 3, the substrate of the radio frequency power device for implementing asymmetric self-alignment of the source, drain and gate according to the present disclosure comprises a base 200 and a GaN buffer layer 201 formed on the base 200, and there are an AlGaN buffer layer 202, a GaN channel layer 203 and an AlGaN isolating layer 204 formed in turn on the GaN buffer layer 201. A gate dielectric layer 205 is formed on the AlGaN isolating layer 204, a gate stack region is formed on the gate dielectric layer 205, wherein the gate stack region includes a gate 206 and a passivating layer on the gate 206. A first gate sidewall 208 is formed on either side of the gate stack region. A drain 211 and a source 212 are formed respectively on the outer side of the first gate sidewalls on the sides of the gate stack region. A second gate sidewall 209 is formed between the first gate sidewall 208 close to one side of the drain 211 and the drain 211. A field plate 214 of the device is formed on the first gate sidewall 208 close to the drain 211, wherein a part of the field plate 214 is connected with the source and extends over the second gate sidewall 209 and the passivating layer 207 along the length of the current channel of the device. A contact 213 of the drain 211 is formed on the drain 211 for connecting the drain 211 to the external electrode.

In the embodiment of the radio frequency power device for implementing asymmetric self-alignment of the source, drain and gate according to the present disclosure as shown in FIG. 1, the drain 211 and the source 212 are located on the GaN channel layer 203 and formed by silicon doped GaN or AlGaN materials.

In the embodiment of the radio frequency power device for implementing asymmetric self-alignment of the source, drain and gate according to the present disclosure as shown in FIG. 2, the drain 211 and the source 212 are located in the AlGaN isolating layer 204 and formed by the silicon iron doped region in the AlGaN isolating layer 204.

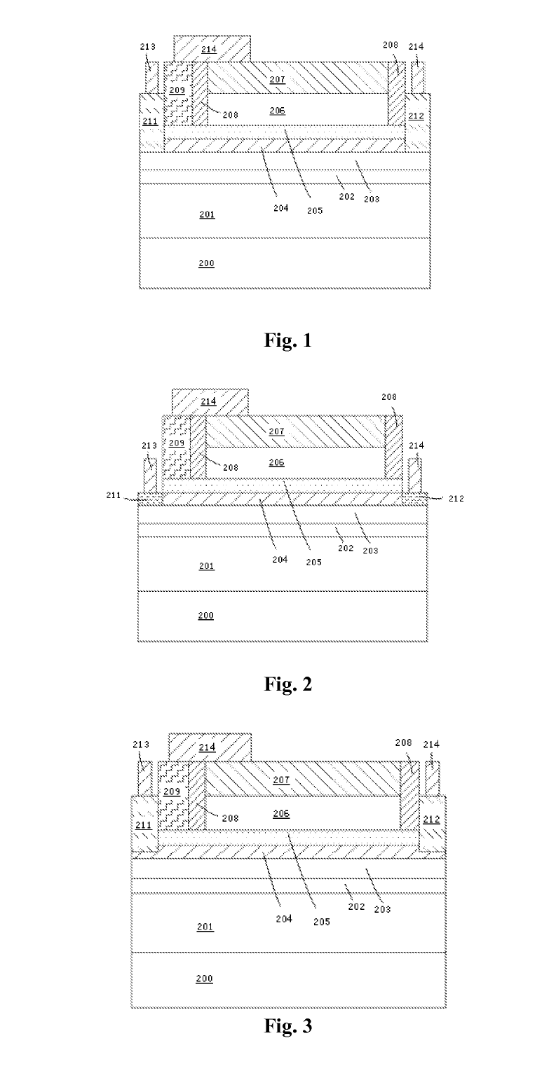

In the embodiment of the radio frequency power device for implementing asymmetric self-alignment of the source, drain and gate according to the present disclosure as shown in FIG. 3, the drain 211 and the source 212 are located on the AlGaN isolating layer 204 and commonly formed by alloy materials.

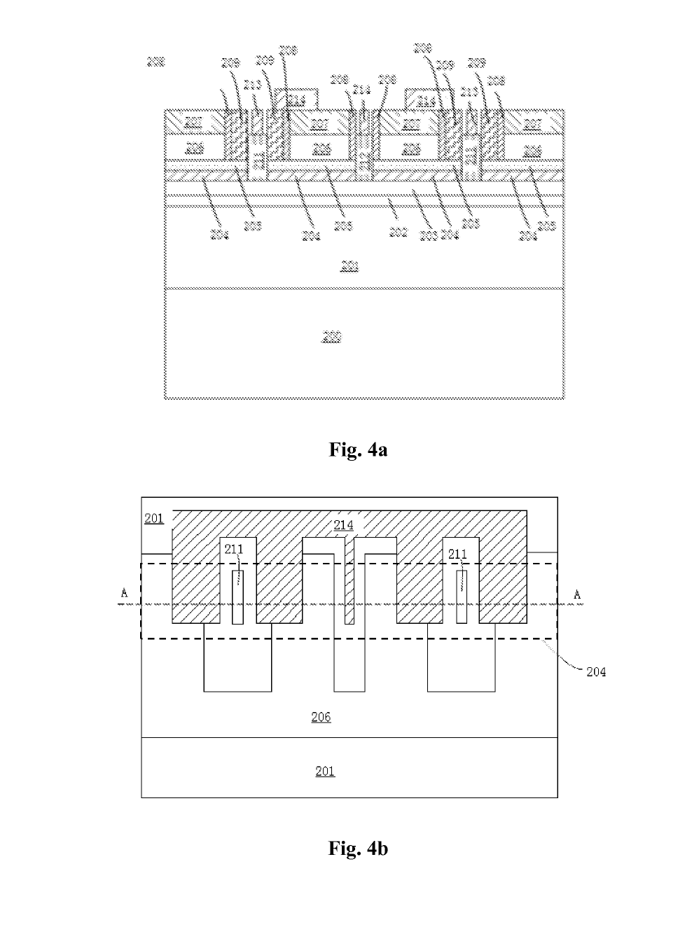

Multiple radio frequency power devices for implementing asymmetric self-alignment of the source, drain and gate according to the present disclosure can make up a radio frequency power device array. FIG. 4 illustrates one embodiment of the radio frequency power device array consisting of the radio frequency power device for implementing asymmetric self-alignment of the source, drain and gate as shown in FIG. 1 disclosed by the present disclosure, wherein FIG. 4b is the vertical view of the radio frequency power device array and FIG. 4a is the cross-sectional view of the structure shown in FIG. 4b along Line A-A. In the embodiment of the radio frequency power device array as shown in FIG. 4, adjacent two radio frequency power devices for implementing asymmetric self-alignment of the source, drain and gate share one source 212 or share one drain 211.

The production methods of the radio frequency power device for implementing asymmetric self-alignment of the source, drain and gate provided by the present disclosure and the radio frequency power device array consisting of the radio frequency power device for implementing asymmetric self-alignment of the source, drain and gate are the same. The following is to describe the process flow for fabricating the structure of the radio frequency power device according to the present disclosure.

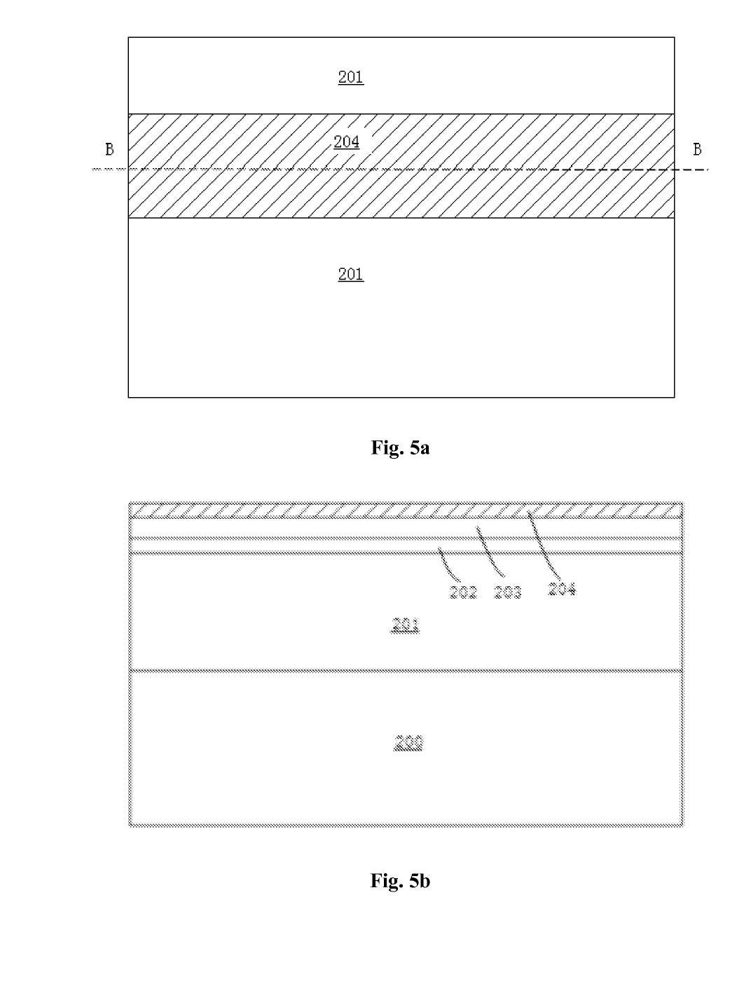

First, as shown in FIG. 5, deposit an about 40 nm thick AlGaN buffer layer 202, an about 40 nm thick GaN channel layer 203 and an about 22 nm thick AlGaN isolating layer 204 in turn on the substrate; deposit a layer of photo-resist on the AlGaN isolating layer 204, and define the location of the active region by masking, exposure and development; and etch way the AlGaN isolating layer 204, the GaN channel layer 203 and the AlGaN buffer layer 201 exposed in turn with a photo-resist as the etching stop layer to form an active region, followed by removal of the resist. Wherein, FIG. 5a is the vertical view of the structure formed and FIG. 5b is the cross-sectional view of FIG. 5a along Line B-B.

The substrate in the embodiment comprises a base 200 and a GaN buffer layer 201 formed on the base 200, and the base 200 can be silicon, SiC or Al₂O₃.

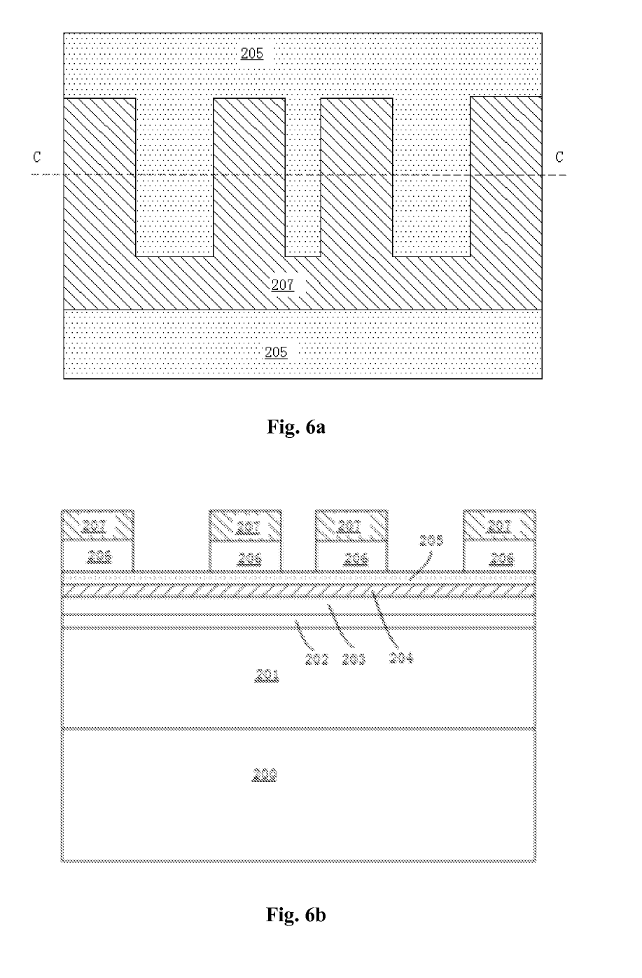

Next, deposit the first layer of insulating film 205, the first layer of conductive film and the second layer of insulating film in turn on the exposed surface of the structure formed; deposit a layer of photo-resist on the second layer of insulating film, and define the location of the device's active region by masking, exposure and development; etch away the second layer of insulating film and the first layer of conductive film exposed in turn with a photo-resist as the etching stop layer, in this way the remaining first layer of conductive film and second layer of insulating film form the gate stack region which comprises the gate 206 of the device and the passivating layer 207 on the gate; after removal of the resist, the structure is as shown in FIG. 6, wherein FIG. 4a is the vertical view of the structure formed and FIG. 6b is the cross-sectional view of FIG. 6 along Line C-C.

The first layer of insulating film 205 can be silicon oxide, silicon nitride, hafnium oxide or Al₂O₃, and the thickness is preferably 8 nm as the gate dielectric layer. The gate 206 can be chromium, nickel or tungsten-containing alloy, such as nickel-gold alloy, palladium-gold alloy, platinum-gold alloy, nickel-platinum alloy or nickel-palladium alloy. The passivating layer 207 can be silicon dioxide or silicon nitride.

Next, deposit the third layer of insulating film on the exposed surface of the structure formed, and etch back the third layer of insulating film formed to form a first gate sidewall 208 on either side of the gate stack region, as shown in FIG. 7. The gate sidewalls 208 can be silicon dioxide or silicon nitride.

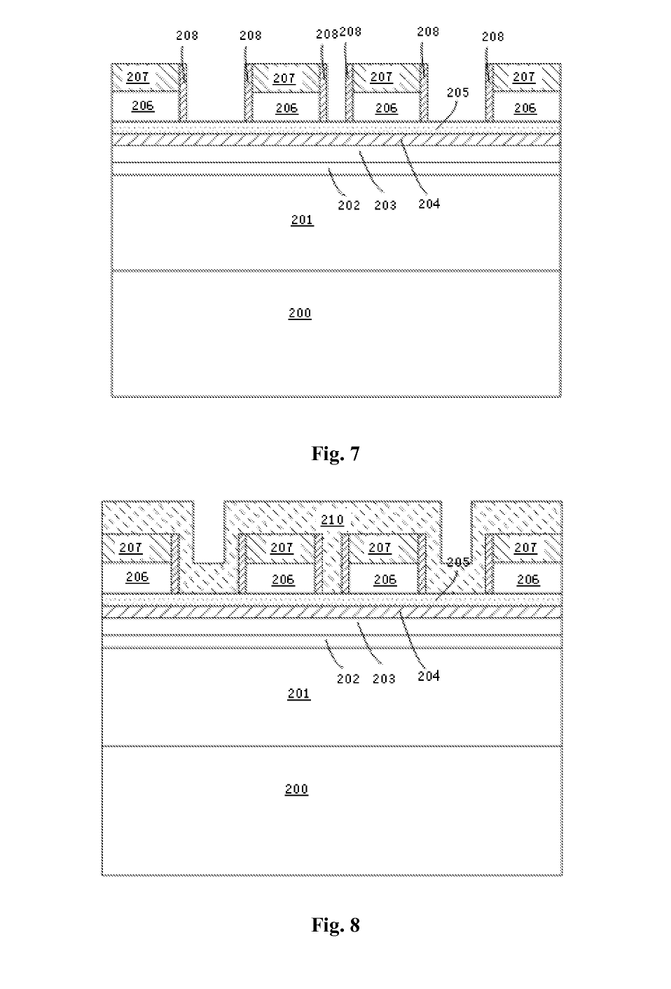

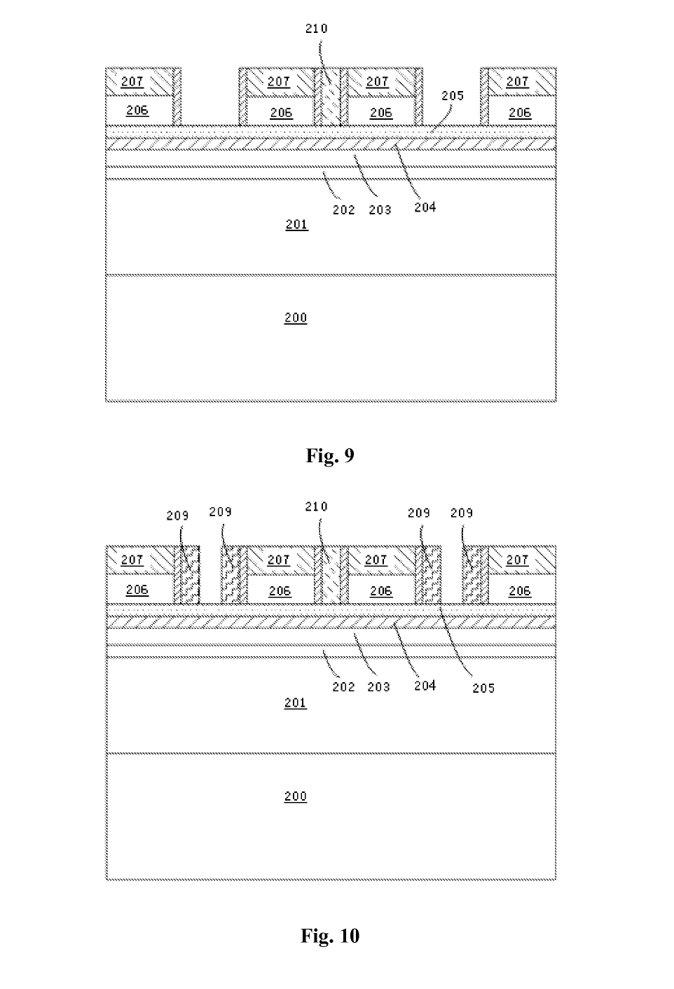

Next, deposit a layer of polysilicon film 210 on the exposed surface of the structure formed, as shown in FIG. 8, and etch back the polysilicon film 210 formed, as shown in FIG. 9.

In a GaN radio frequency power device array, the polysilicon is etched away except that at the location of the source when etching the polysilicon film 210 by controlling the distance between gates.

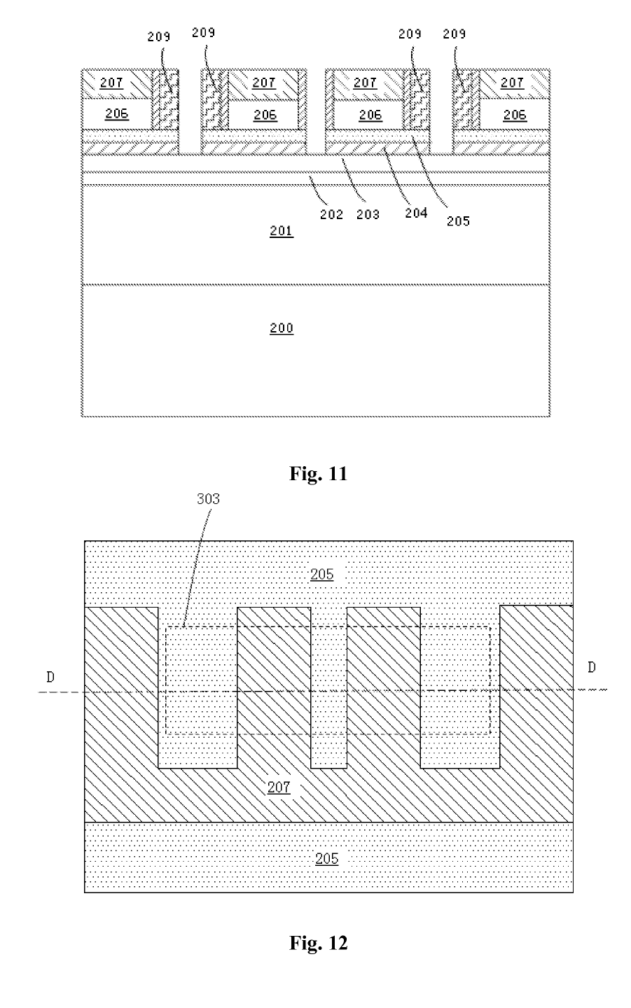

Next, deposit the fourth layer of insulating film on the exposed surface of the structure formed, and etch the fourth layer of insulating film formed to form a second gate sidewall 209 on one side of the gate stack region, as shown in FIG. 10. Next, etch away the remaining polysilicon film 210, and continue to etch away the first layer of insulating film 205 and the AlGaN isolating layer 204 exposed, to expose the GaN channel layer 203, as shown in FIG. 11.

Next, deposit a layer of photo-resist on the exposed surface of the structure formed, form a pattern by masking, exposure and development, and expose the locations of the source and the drain by mean of a pattern, as shown in FIG. 12. FIG. 12 is the vertical view of the structure formed, wherein the dotted box 303 represents the location of the pattern formed.

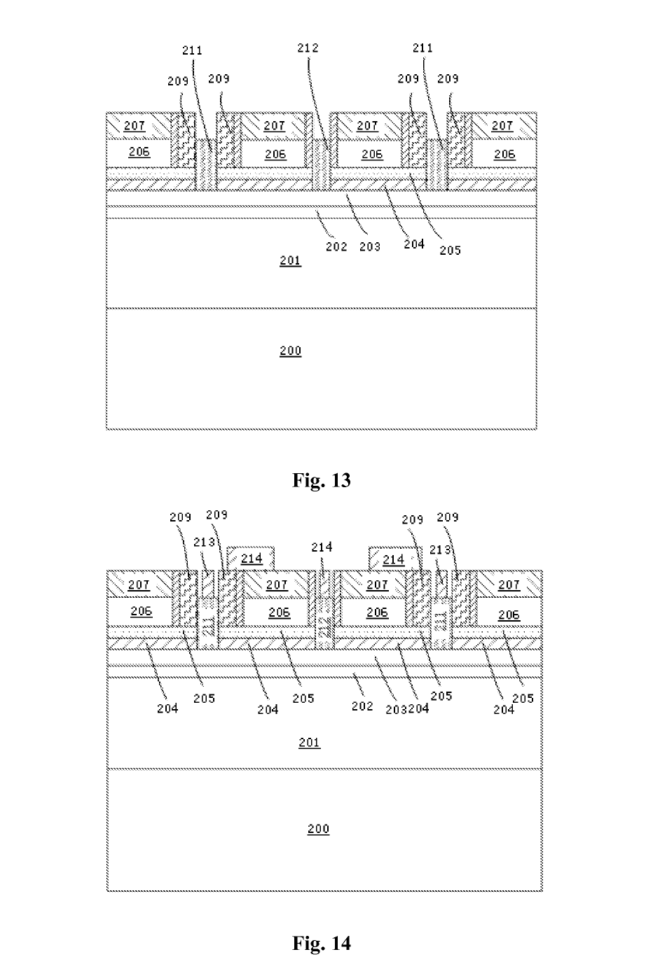

Next, grow silicon doped GaN or AlGaN by the epitaxy process to form the source 212 and the drain 211 of the device on the exposed GaN channel layer 203, remove the photo-resist and polysilicon GaN, as shown in FIG. 13.

Finally, deposit a new layer of photo-resist on the exposed surface of the structure formed, define the location of the field plate, source and drain of the device by masking, exposure and development, deposit the second layer of conductive film, wherein the second layer of conductive film can be titanium-aluminium alloy, nickel-aluminium alloy, nickel-platinum alloy or nickel-gold alloy, remove the second layer of conductive film deposited on the photo-resist by use of the lift-off process known in the field and keep the second layer of conductive film not deposited on the photo-resist to form the field plate 214 of the device on the first gate sidewall 208 close to one side of the drain 211, wherein the field plate 214 is connected with the source 212, and form the contact 213 of the drain for connecting the drain to the external electrode, as shown in FIG. 14.

The structure of the radio frequency power device array shown in FIG. 14 corresponds to that of the radio frequency power device for implementing asymmetric self-alignment of the source, drain and gate shown in FIG. 3.

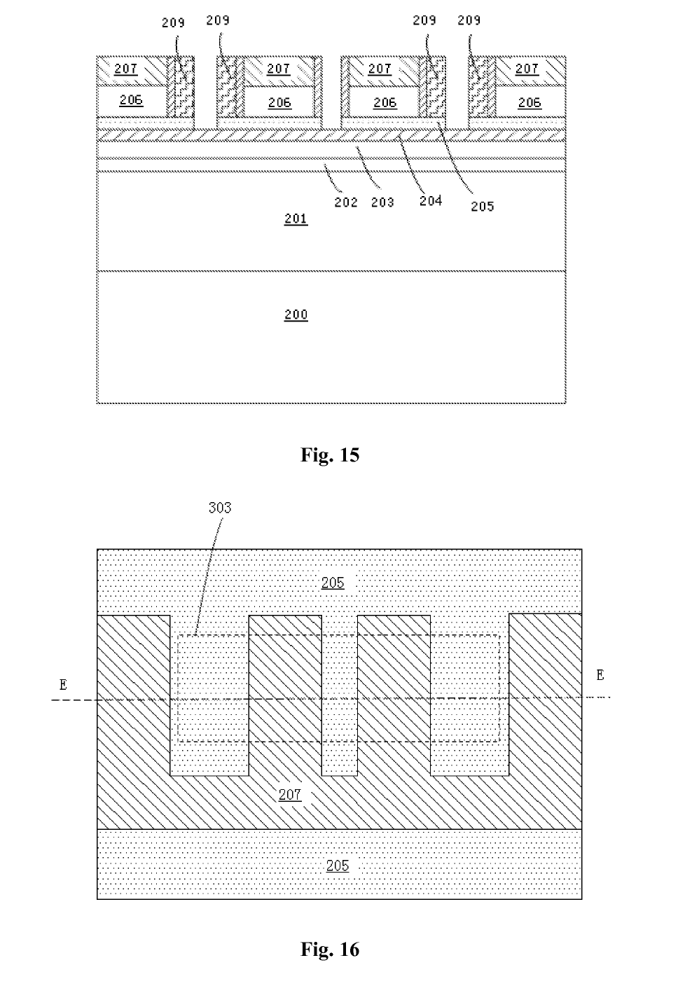

In the production method of the radio frequency power device array described in FIG. 4 to FIG. 14, it is workable to only etch away the first layer of insulating film 205 exposed instead of the AlGaN isolating layer 204 after the remaining polysilicon film 210 is etched away, as shown in FIG. 15; and then deposit a layer of photo-resist on the exposed surface of the structure formed, form a pattern by masking, exposure and development, and expose the location of the source and gate by means of a pattern, as shown in FIG. 16. FIG. 16 is the vertical view of the structure formed, wherein the dotted box 303 represents the location of the pattern formed.

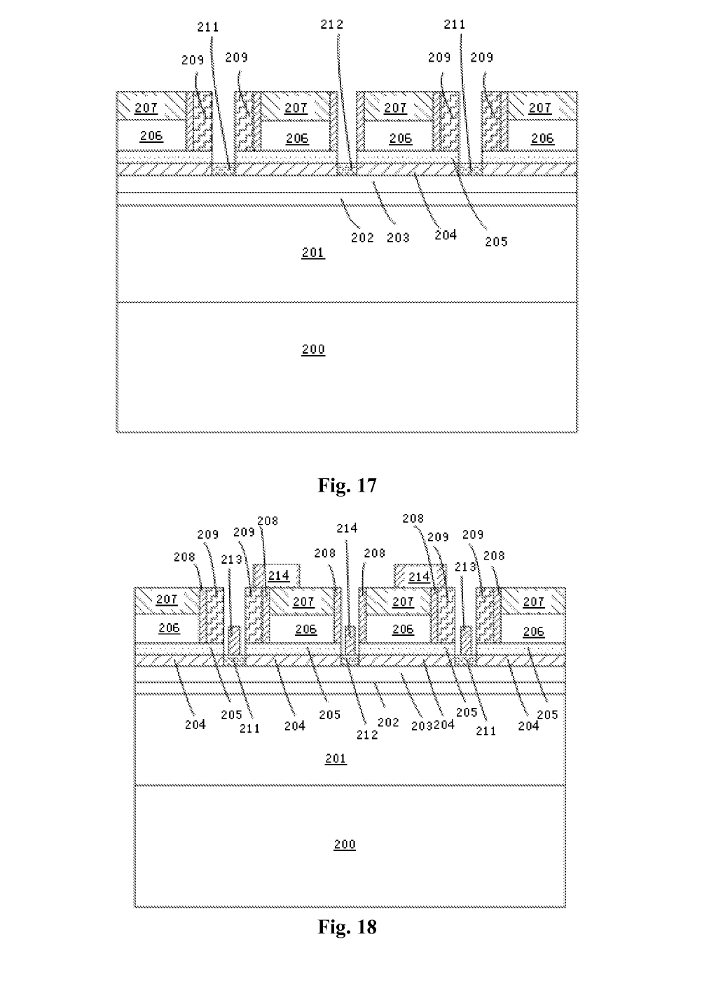

Next, implant silicon irons into the AlGaN isolating layer 204 by the iron implanting process to form the source 212 and the drain 211 of the device, and carry out rapid thermal processing after removal of the photo-resist, as shown in FIG. 17.

Finally, deposit a new layer of photo-resist on the exposed surface of the structure formed, define the location of the field plate, source and drain of the device by masking, exposure and development, and then deposit the second layer of conductive film, wherein the second layer of conductive film can be titanium-aluminium alloy, nickel-aluminium alloy, nickel-platinum alloy or nickel-gold alloy, remove the second layer of conductive film deposited on the photo-resist by use of the lift-off process known in the field and keep the second layer of conductive film not deposited on the photo-resist to form the field plate 214 of the device on the first gate sidewall close to one side of the drain 211, wherein the field plate 214 is connected with the source 212, and form the contact 213 of the drain for connecting the drain to the external electrode, as shown in FIG. 18.

The structure of the radio frequency power device array shown in FIG. 18 corresponds to that of the radio frequency power device for implementing asymmetric self-alignment of the source, drain and gate shown in FIG. 2.

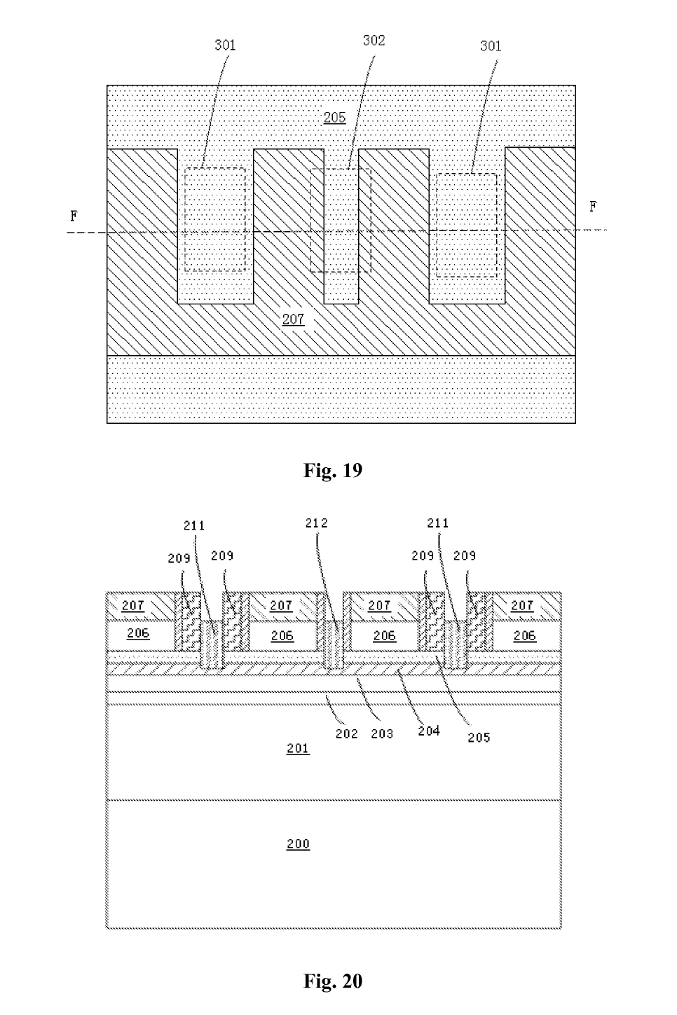

In the production method of the radio frequency power device array described above, it is workable to not carry out the iron implanting process after etching away the remaining polysilicon film 210 and continuing to etch away the first layer of insulating film 205 exposed to expose the AlGaN isolating layer 204; deposit a layer of photo-resist on the exposed surface of the structure formed instead, and form a pattern by masking, exposure and development to define the locations of the source and the drain, as shown in FIG. 19. FIG. 19 is the vertical view of the structure formed, wherein the dotted boxes 301, 302 represent the location of the drain pattern and source pattern formed respectively.

Next, form the source 212 and the drain 211 of the device on the AlGaN isolating layer 204 by use of the lift-off process and the alloying process, as shown in FIG. 20. The process is as follows: first, deposit a layer of conductive film, such as titanium/aluminium/nickel/gold alloy; remove the conductive film deposited on the photo-resist by use of the lift-off process, but keep the conductive film not deposited on the photo-resist, and form a good source-drain contact by high-temperature thermal annealing;

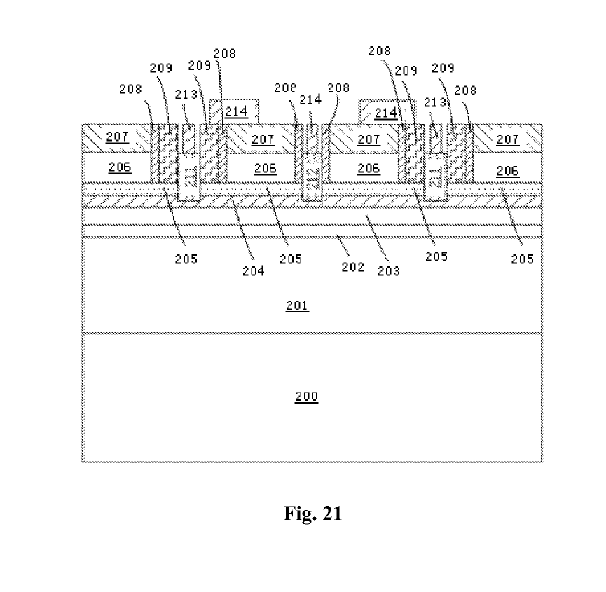

finally, deposit a new layer of photo-resist on the exposed surface of the structure formed, define the location of the field plate, source and drain of the device by masking, exposure and development, deposit the second layer of conductive film, wherein the second layer of conductive film can be titanium-aluminium alloy, nickel-aluminium alloy, nickel-platinum alloy or nickel-gold alloy; and then remove the second layer of conductive film deposited on the photo-resist by use of the lift-off process known in the field and keep the second layer of conductive film not deposited on the photo-resist to form the field plate 214 of the device on the first gate sidewall close to one side of the drain 211, wherein the field plate 214 is connected with the source 212, and form the contact 213 of the drain for connecting the drain to the external electrode, as shown in FIG. 21.

The structure of the radio frequency power device array shown in FIG. 21 corresponds to that of the radio frequency power device for implementing asymmetric self-alignment of the source, drain and gate shown in FIG. 3.

As described above, many other embodiments with great difference can be formed without deviating from the spirit of the present disclosure. It should be understood that the present disclosure is not limited to the specific embodiments described in the specification except those limited by the claims attached.

### INDUSTRIAL APPLICABILITY

In the radio frequency power device for implementing asymmetric self-alignment of the source, drain and gate according to the present disclosure, gate sidewalls are utilized to implement the self-position alignment of the source, drain and gate, thereby reducing parameter drift of products; besides, the source and drain of the device can be formed directly by the alloying process, the iron implanting process or epitaxy process after formation of the gate since the gate is protected by the passivating layer, thereby reducing the parasitic source-drain resistances and enhancing the electrical properties of the radio frequency power device.

What is claimed is:

1. A radio frequency power device for implementing asymmetric self-alignment of the source, drain and gate, comprising:
an AlGaN buffer layer, a GaN channel layer and an AlGaN isolating layer formed in turn on the substrate;
a gate dielectric layer formed on the AlGaN isolating layer;
wherein, said device also comprises:
a gate stack region formed on the gate dielectric layer, including a gate and a passivating layer on the gate;
a first gate sidewall formed on either side of the gate stack region;
a drain and a source formed respectively on the outer side of the first gate sidewalls on both sides of the gate stack region;
a second gate sidewall formed between the first gate sidewall close to one side of the drain and the drain.

2. The radio frequency power device for implementing asymmetric self-alignment of the source, drain and gate as claimed in claim 1, wherein a field plate is formed on the first gate sidewall close to the drain, wherein the field plate is connected with the source and extends over the second gate sidewall and the passivating layer on the gate along the length of the current channel of the device.

3. The radio frequency power device for implementing asymmetric self-alignment of the source, drain and gate as claimed in claim 1, wherein the source and the drain are located on the AlGaN isolating layer and formed by alloy materials.

4. The radio frequency power device for implementing asymmetric self-alignment of the source, drain and gate as claimed in claim 1, wherein the source and the drain are located in the AlGaN isolating layer and formed by the silicon iron doped region in the AlGaN isolating layer.

5. The radio frequency power device for implementing asymmetric self-alignment of the source, drain and gate as claimed in claim 1, wherein the source and the drain are located on the GaN channel layer and formed by silicon doped GaN or AlGaN materials.

6. A production method of the radio frequency power device for implementing asymmetric self-alignment of the source, drain and gate as claimed in claim 1, wherein the specific steps are as follows:
deposit an AlGaN buffer layer, a GaN channel layer and an AlGaN isolating layer in turn on the substrate;
etch the AlGaN isolating layer, the GaN channel layer and the AlGaN buffer layer in turn to form an active region with a photo-resist as the etching stop layer, followed by removal of the resist;
deposit the first layer of insulating film, the first layer of conductive film and the second layer of insulating film in turn on the exposed surface of the structure formed;
define the location of the gate stack region of the device by photo-etching and development;
etch away the second layer of insulating film and the first layer of conductive film exposed in turn with a photo-resist as the etching stop layer, followed by removal of the resist, in this way the remaining first layer of conductive film and second layer of insulating film form the gate stack region which comprises the gate of the device and the passivating layer on the gate;
deposit the third layer of insulating film on the exposed surface of the structure formed, and etch the third layer of insulating film to form a first gate sidewall on either side of the gate stack region;
deposit a layer of polysilicon on the exposed surface of the structure formed, etch back the polysilicon formed, but only the polysilicon at the source is not etched away;
deposit the fourth layer of insulating film on the exposed surface of the structure formed, and etch the fourth layer of insulating film to form the second gate sidewall on the side of the gate stack region close to the drain;
etch away the remaining polysilicon, and continue to etch away the first layer of insulating film exposed.

7. The production method of the radio frequency power device for implementing asymmetric self-alignment of the source, drain and gate as claimed in claim 6, wherein, also including:
form a pattern by photo-etching to define the locations of the source and the drain respectively;
form the source and drain of the device by the lift-off process and the alloying process;
form a field plate on the first gate sidewall close to the drain, wherein the field plate is connected with the source and extends over the second gate sidewall and the passivating layer on the gate along the length of the current channel of the device.

8. The production method of the radio frequency power device for implementing asymmetric self-alignment of the source, drain and gate as claimed in claim 6, wherein, also including:
form a pattern by the photo-etching process and expose the locations of the source and the drain by means of a pattern;
implant silicon irons into the AlGaN isolating layer by the iron implanting process to form the source and drain of the device;
form a field plate on the first gate sidewall close to the drain, wherein the field plate is connected with the source and extends over the second gate sidewall and the passivating layer on the gate along the length of the current channel of the device.

9. The production method of the radio frequency power device for implementing asymmetric self-alignment of the source, drain and gate as claimed in claim 6, wherein, also including:
continue to etch away the exposed AlGaN isolating layer to expose the GaN channel layer formed;
form a pattern by the photo-etching process and expose the locations of the source and the drain by means of a pattern;
grow silicon doped GaN or AlGaN by the epitaxy process to form the source and the drain of the device on the exposed GaN channel layer;
form a field plate on the first gate sidewall close to the drain, wherein the field plate is connected with the source and extends over the second gate sidewall and the passivating layer on the gate along the length of the current channel of the device.

10. The production method of the radio frequency power device for implementing asymmetric self-alignment of the source, drain and gate as claimed in claim 6, wherein the first layer of insulating film is any one of silicon oxide, silicon nitride, hafnium oxide or Al₂O₃, while the second layer of insulating film, the third layer of insulating film and the fourth layer of insulating film are any one of silicon oxide or silicon nitride.

11. The production method of the radio frequency power device for implementing asymmetric self-alignment of the source, drain and gate as claimed in claim 6, wherein the first layer of conductive film is chromium, nickel or tungsten-containing alloy.
